(19) United States
(12) Patent Application Publication
(10) Pub. No.: US 2017/0059640 A1
(43) Pub. Date: Mar. 2, 2017

(54) SYSTEM FOR MONITORING A FUSE LINK, FUSE TUBE ASSEMBLY AND FUSE CUTOUT INCLUDING SAME

(71) Applicant: COOPER TECHNOLOGIES COMPANY, HOUSTON, TX (US)

(72) Inventors: GREGG JAMES HAENSGEN, MENOMONEE FALLS, WI (US); RICHARD WILLIAM LUCAS, ZIMMERMAN, MN (US); MICHAEL BRUCE PITEL, CEDARBURG, WI (US); BRUCE DOUGLAS HOEPPNER, BROOKFIELD, WI (US)

(73) Assignee: COOPER TECHNOLOGIES COMPANY, HOUSTON, TX (US)

(21) Appl. No.: 14/840,467

(22) Filed: Aug. 31, 2015

(51) Int. Cl. G01R 31/07; H01H 85/38

(52) U.S. Cl. CPC G01R 31/07; H01H 85/38

(57) ABSTRACT

A system for monitoring one or more aspects of a fuse tube assembly of a fuse cutout comprises: a housing structured to be disposed adjacent to, and coupled to the fuse tube assembly; a power source disposed in the housing; a processing unit disposed in the housing and electrically coupled to the power source; and a motion detecting unit disposed in the housing and electrically coupled to the processing unit, the motion detecting unit being structured to detect one or both of position or movement of the housing.

### BACKGROUND

Field

The disclosed concept relates generally to electrical disconnects, and more particularly, to fuse cutouts providing current sensing and one or both of position or motion detecting. The disclosed concept further relates to fuse tube assemblies which provide current sensing and one or both of position or motion detecting for use in such cutouts. The disclosed concept also relates to a sensing system which provides for current sensing and one or both of position or motion detecting for use with fuse links.

Background Information

The primary purpose of a fuse cutout is to provide protection for power distribution systems and the various apparatus on those power lines such as transformers and capacitor banks. An over current in the system can occur under various conditions, such as an animal or tree contacting the power lines or more than one power line contacting each other.

Fuse cutouts and fuse links utilized therein are well known. A typical fuse cutout includes a hollow insulative fuse tube having conductive ferrules mounted to the opposite ends thereof. One ferrule (often called the “exhaust” ferrule) is located at an exhaust end of the fuse tube and usually includes a trunnion which interfits with a trunnion pocket or hinge of a first contact assembly carried by one end of an insulator. The other ferrule is normally held and latched by a second contact assembly carried by the other end of the insulator so that the fuse tube is normally parallel to, but spaced from, the insulator. The insulator is mountable to the cross-arm of a utility pole or a similar structure. The fuse link is located within the fuse tube with its ends respectively electrically continuous with the ferrules. One point of an electrical circuit is connected to the first contact assembly, while another point of the circuit is connected to the second contact assembly. Often, the insulator and the fuse tube are oriented generally perpendicular to the ground so that the exhaust ferrule and the first contact assembly are located below the other ferrule and the second contact assembly. The fuse tube may include a high burst strength outer portion—for example, a fiber-glass-epoxy composite having an arc-extinguishing material within the inner portions thereof. Normal currents flowing through the electrical circuit flow without affecting the fuse link. Should a fault current or other overcurrent, to which the fuse link is designed to respond, occur in the circuit, the fuse link operates as described in more detail hereinafter.

Operation of the fuse link permits the upper ferrule to disengage itself from the upper contact assembly, whereupon the fuse tube rotates downwardly due to coaction of the trunnion and the hinge. If the fuse link operates properly, current in the circuit is interrupted and the rotation of the fuse tube gives a visual indication that the cutout has operated to protect the circuit, e.g., dropout operation to a so-called dropout position. However, fuses will often trip when current over a predetermined threshold is applied, but due to mechanical failure, the fuse will not drop, and thus appear to be still functional when observed from the ground. Additionally, due to the force of the fuse blowing, the fuse holder may swing off the bracket and fall to the ground.

Currently, detection of blown cutout fuses is a manual and reactive process. Today there is also no data available to determine the reason for the blowing of a fuse. Utilities will receive calls from customers or reports from downstream IEDs (intelligent electronic device) that the power has gone out in the area. Expensive high voltage line crews are then dispatched to find the problem source. Crews take time driving the lines in the area to find the problem which may be as simple as a blown fuse or another more complicated issue with the distribution system. Furthermore, a blown fuse may not be immediately apparent if it has not dropped as it should due to mechanical failure.

Accordingly, there is room for improvement in fuse cutouts.

There is thus also room for improvement in fuse links for use in fuse cutouts.

### SUMMARY

These needs and others are met by embodiments of the disclosed concept, which provides for monitoring of various aspects of a fuse cutout and related components.

In accordance with one aspect of the disclosed concept, a system for monitoring one or more aspects of a fuse tube assembly of a fuse cutout is provided. The system comprises: a housing structured to be disposed adjacent to, and coupled to the fuse tube assembly; a power source disposed in the housing; a processing unit disposed in the housing and electrically coupled to the power source; and a motion detecting unit disposed in the housing and electrically coupled to the processing unit, the motion detecting unit being structured to detect one or both of position or movement of the housing.

The system may further comprise a transmitting unit electrically coupled to the processing unit, the transmitting unit being adapted to transmit information from the processing unit to one or more receiving units positioned a distance from the housing.

The system may further comprise a current sensing unit disposed in the housing and electrically coupled to the processing unit, the current sensing unit being structured to detect current passing through a fuse link disposed in a fuse tube of the fuse tube assembly.

The motion detecting unit may comprise at least one of an accelerometer or a gyroscope.

The housing may be structured to be disposed around a fuse tube of the fuse tube assembly.

The housing may comprise a first portion and a second portion which are moveably coupled with respect to each other via a number of hinge members.

The power source may comprise a solar cell.

The power source may comprise an energy harvesting system structured to harvest energy from a flow of current passing through a fuse link disposed in a fuse tube of the fuse tube assembly.

The processing unit may be structured to receive and record data along with relevant time information from one or more of the motion detecting unit and current sensing unit.

In accordance with another aspect of the disclosed concept, a fuse tube assembly for use in a fuse cutout is provided. The fuse tube assembly comprises: a fuse tube structured to receive a fuse link therein; an upper ferrule assembly coupled to the fuse tube at or about an upper end thereof, the upper ferrule assembly structured to engage an upper contact assembly of the fuse cutout; a lower ferrule assembly coupled to the fuse tube at or about an opposite lower end thereof, the upper ferrule assembly structured to engage a lower contact assembly of the fuse cutout; and a system for monitoring one or more aspects of the fuse tube assembly. The system comprises: a housing disposed adjacent to, and coupled to the fuse tube; a power source disposed in the housing; a processing unit disposed in the housing and electrically coupled to the power source; and a motion detecting unit disposed in the housing and electrically coupled to the processing unit, the motion detecting unit being adapted to detect one or both of position or movement of the housing.

The fuse tube assembly may further comprise a transmitting unit electrically coupled to the processing unit, the transmitting unit being adapted to transmit information from the processing unit to one or more receiving units positioned a distance from the housing.

The fuse tube assembly may further comprise a current sensing unit disposed in the housing and electrically coupled to the processing unit.

The motion detecting unit may comprise at least one of an accelerometer or a gyroscope.

The housing may be disposed around the fuse tube assembly.

The housing may comprise a first portion and a second portion which are moveably coupled with respect to each other via a number of hinge members.

The power source may comprise a solar cell.

The power source may comprise an energy harvesting system structured to harvest energy from a flow of current passing through a fuse link disposed in the fuse tube.

In accordance with another aspect of the disclosed concept, a fuse cutout is provided. The fuse cutout comprises: an insulator; a mounting member extending from the insulator for securing the cutout to a utility pole or other structural member; an upper contact assembly coupled to an upper end of the insulator; a lower contact assembly coupled to a lower end of the insulator; and a fuse tube assembly. The fuse tube assembly comprises: a fuse tube structured to receive a fuse link therein; an upper ferrule assembly coupled to the fuse tube at or about an upper end thereof, the upper ferrule assembly engaged with the upper contact assembly; a lower ferrule assembly coupled to the fuse tube at or about an opposite lower end thereof, the upper ferrule assembly engaged with the lower contact assembly of the fuse cutout; and a system for monitoring one or more aspects of the fuse tube assembly. The system comprises: a housing disposed adjacent to, and coupled to the fuse tube; a power source disposed in the housing; a processing unit disposed in the housing and electrically coupled to the power source; and a motion detecting unit disposed in the housing and electrically coupled to the processing unit, the motion detecting unit being adapted to detect movement of the housing.

The system of the fuse cutout may further comprise a transmitting unit electrically coupled to the processing unit, the transmitting unit being adapted to transmit information from the processing unit to one or more receiving units positioned a distance from the housing.

### BRIEF DESCRIPTION OF THE DRAWINGS

A full understanding of the disclosed concept can be gained from the following description of the preferred embodiments when read in conjunction with the accompanying drawings in which:

FIG. 1 is a side elevation view of a fuse cutout including a fuse tube assembly shown in a closed position in accordance with an example embodiment of the disclosed concept;

FIG. 2 is a side elevation view of the fuse cutout of FIG. 1 with the fuse tube assembly shown in an opening position;

FIG. 3 is a side elevation view of the fuse cutout of FIG. 1 showing the fuse tube assembly exploded from the cutout;

FIGS. 4 and 5 are isometric views of a housing for a system for monitoring a fuse link in accordance with an example embodiment of the disclosed concept;

FIG. 6 is an exploded view of the housing of FIGS. 4 and 5;

FIG. 7 is a side elevation view of the fuse cutout of FIG. 1 shown with the housing of FIGS. 4-6 shown in an uncoupled position; and

FIG. 8 is a schematic diagram of a system for monitoring a fuse link in accordance with an example embodiment of the disclosed concept.

### DESCRIPTION OF THE PREFERRED EMBODIMENTS

Directional phrases used herein, such as, for example, left, right, front, back, top, bottom and derivatives thereof, relate to the orientation of the elements shown in the drawings and are not limiting upon the claims unless expressly recited therein.

As employed herein, the word “number” shall mean a quantity of one, or any integer greater than one (i.e., a plurality).

As employed herein, the statement that two or more parts are “coupled” together shall mean that the parts are joined together either directly or joined through one or more intermediate parts.

As employed herein, the statement that two or more parts are “selectively coupled” shall mean that the parts are secured together either directly or through one or more intermediate parts in a manner which may be readily undone.

As employed herein, “processing device” or “processing unit” shall be used to refer to a microcontroller or any other suitable processing device and related memory components employed by such device in carrying out electronic processing operations. Examples of suitable processing devices or units includes, without limitation, microprocessors, embedded computers, desktop or rack computers, programmable logic controllers, SCADA systems, and intelligent displays.

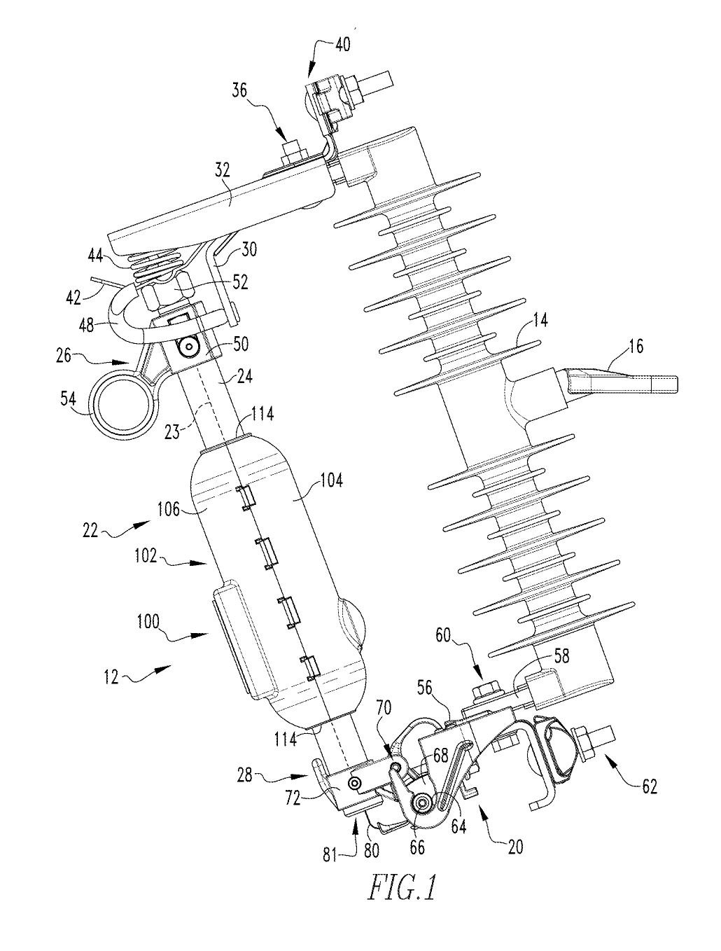

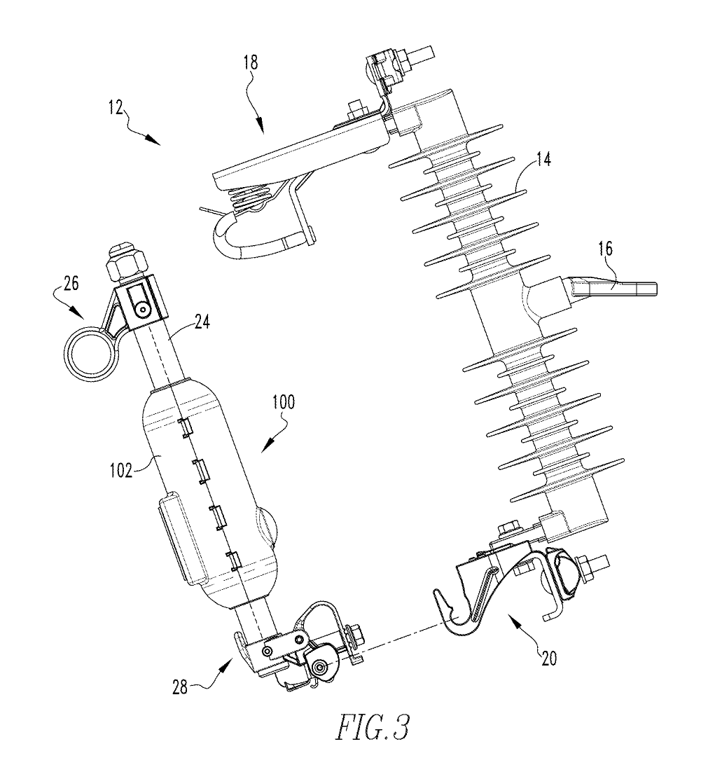

Referring to FIGS. 1-3, there is shown an improved fuse cutout 12 in accordance with an example embodiment of the disclosed concept. Fuse cutout 12 includes an insulator 14 and a mounting member 16 extending therefrom. The mounting member 16 permits mounting of the insulator 14 and the fuse cutout 12 to an upright or a cross-arm of a utility pole or the like (not shown). Affixed to the upper end of the insulator 14 is an upper contact assembly, generally designated 18. Further, affixed to the lower end of the insulator 14 is a lower contact assembly, generally designated 20. The fuse cutout 12 also includes a fuse tube assembly 22 that in the normal closed, circuit-connected or unoperated condition of the cutout 12 may be maintained in the generally vertical, slightly angled position such as shown in FIG. 1.

Continuing to refer to FIGS. 1-3, details of the fuse tube assembly 22 will now be discussed. The fuse tube assembly 22 includes a removable fuse link 23 (shown in dashed line in FIG. 1) disposed within, and extending generally the length of an insulative fuse tube 24. Fuse tube 24 may comprise an epoxy-fiber-glass composite outer shell lined with an arc-extinguishing material or may be formed from one or more other suitable materials. Mounted or affixed at or about an upper end of the fuse tube 24 is an upper ferrule assembly 26, while at or about an opposite lower or exhaust end of the fuse tube 24 is a lower or exhaust ferrule assembly 28. In the position of the fuse tube assembly 22 depicted in FIG. 1, the lower ferrule assembly 28 is held by the lower contact assembly 20, while the upper ferrule assembly 26 is held, and latched against movement, by the upper contact assembly 18.

Referring now to FIG. 1, the upper contact assembly 18 includes a support bar 30 and a recoil arm and contact hood 32 which runs generally parallel to a portion of the support bar 30. Near the top of the insulator 14, the bar 30 and the arm 32 are mounted by a fastener or the like at 36 to a portion of a connector assembly 40 that is affixed to the top of the insulator 14. The connector assembly 40 facilitates the connection to the upper contact assembly 18 to a cable or conductor of a high-voltage circuit.

The upper contact assembly 18 also includes a spring contact arm 42 and a backup spring 44 that is positioned between the spring contact arm 42 and the recoil arm and contact hood 32. The backup spring 44 provides high contact pressure between the contact arm 42 and the top of the fuse tube assembly 22 as will be explained in more detail hereinafter. As is typical in the power industry, the support bar 30 at a downwardly bent portion includes attachment hooks 48 for cooperation with a portable loadbreak tool.

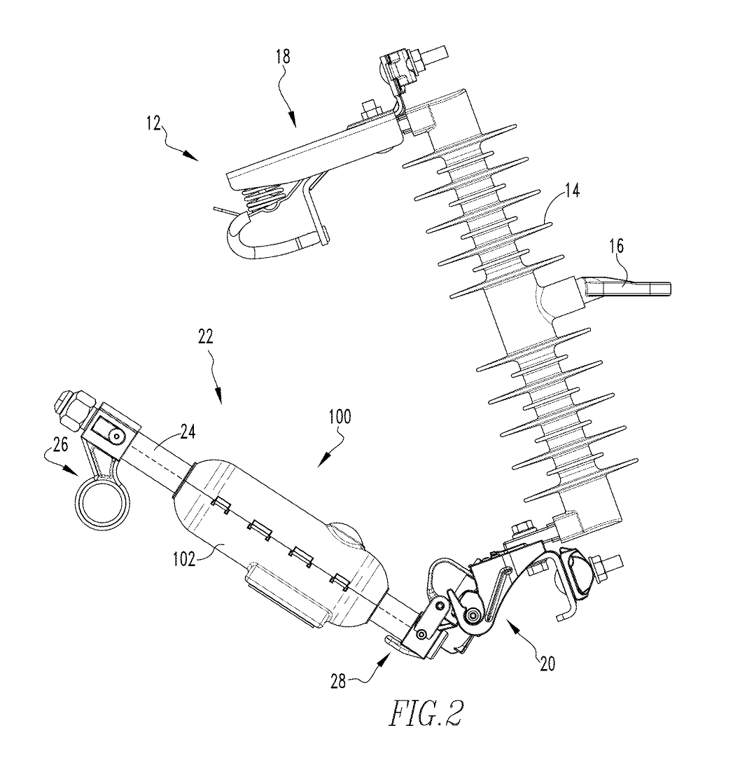

The upper ferrule assembly 26 of the fuse tube assembly 22 includes a ferrule 50 affixed to the upper end of the fuse tube 24. The ferrule 50 typically includes a threaded portion (not shown) onto which is threaded a contact cap 52. The contact cap 52 is configured so as to fit into and be held when the fuse tube assembly 22 is in the position shown in FIG. 1, e.g., by an indentation or concavity (not shown) formed in the spring contact 42. The ferrule 50 typically also includes a pull ring 54 which may be engaged by a hook stick or the like to move the upper ferrule assembly 26 away from the upper contact assembly 18 while the lower ferrule assembly 28 rotates in the lower contact assembly 20, such as generally shown in FIG. 2.

In view of the nature of high voltage circuits, this opening movement of the fuse tube assembly 22 must be effected while the circuit connected to the cutout 12 is de-energized or else an arc will form between the upper ferrule assembly 26 and the upper contact assembly 18. The fuse tube assembly 22 may also be opened by initially attaching a portable loadbreak tool (not shown) between the attachment hooks 48 and the pull ring 54. Such a portable loadbreak tool permits the fuse tube assembly 22 to be opened with the circuit energized, momentarily having transferred thereto the flow of current in the circuit 10 and interrupting such current internally thereof.

The lower contact assembly 20 includes a support member 56 attached to a mount 58 by a fastener or the like at 60. The support member 56 carries a connector 62, such as a parallel groove connector, to facilitate connection of the lower contact assembly 20 to another cable or conductor of the high-voltage circuit in which the fuse cutout 12 is to be used. The support member 56 provides a hinge function via trunnion pockets 64. The trunnion pockets are designed to cooperate with and hold outwardly extending portions 66 of a trunnion 68 carried by the fuse tube 24. Specifically, a lower ferrule 72 affixed to the fuse tube 24 pivotally mounts the trunnion 68 at a toggle joint 70. Thus, the trunnion 68 functions as a toggle member and defines a double pivot mounting for the fuse tube 24, the first pivot being defined at the toggle joint 70 and the second pivot being defined by the extending portions 66 of the trunnion 68 within the trunnion pockets 64 of the hinge support member 56.

As hereinafter described, the trunnion 68 and the ferrule 72 are normally rigidly held in the relative position depicted in FIG. 1. In this normal relative position of the trunnion 68 and the ferrule 72, the contact cap 52 is engaged by the spring contact 42 to maintain the fuse tube assembly 22 in the position depicted in FIG. 1. When the fuse link 23 within the fuse tube 24 operates, the trunnion 68 and the ferrule 72 are no longer rigidly held, and the ferrule 72 may rotate downwardly relative to the trunnion 68 about the toggle joint 70. This movement of the ferrule 72 permits the contact cap 52 to disengage the spring contact 42, following which the entire fuse tube assembly 22 rotates about the lower contact assembly 20 via rotation of the extending portions 66 in the trunnion pockets 64.

In use, the fuse link 23 is first installed into the fuse tube assembly 22 by removing the contact cap 52 and inserting the fuse link 23 into the fuse tube 24 from the upper end thereof. A portion of the fuse link 23 abuts a shoulder (not shown) at the top of the ferrule 50, following which the contact cap 52 is threaded back onto the ferrule 50. A flexible stranded cable 80 forming a part of the fuse link exits an exhaust opening at 81 in the lower or exhaust end of the fuse tube 24.

It is to be appreciated that the portions of the fuse cutout 12 and fuse tube assembly 22 described thus far are generally known and are given for exemplary purposes only and as such are not intended to limit the scope of the disclosed concept. Accordingly, it is to be further appreciated that embodiments of the disclosed concept, described in further detail below, may be employed in fuse cutouts and with fuse tube assemblies other than those previously described herein without varying from the scope of the disclosed concept.

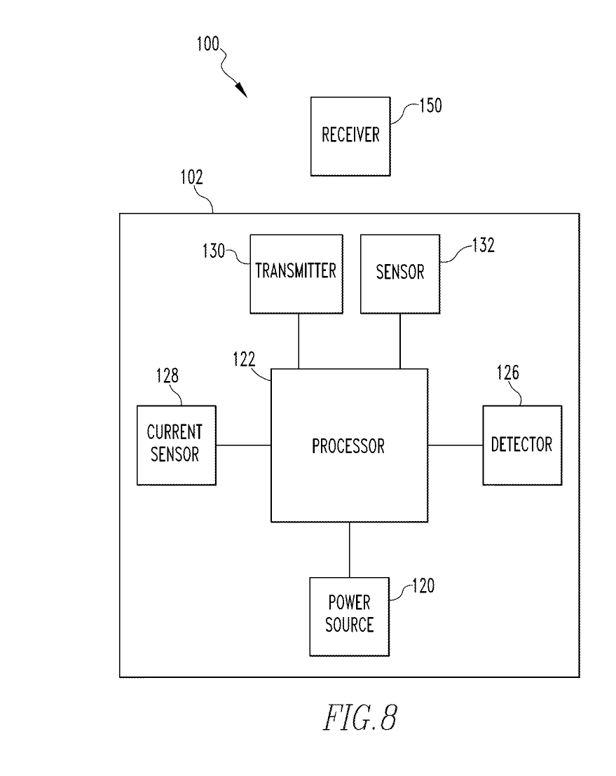

Referring again to FIGS. 1-3 as well as to FIG. 8, fuse tube assembly 22 further includes a monitoring system 100 for monitoring one or more aspects of the fuse tube and/or the fuse link 23 disposed therein. System 100 includes a housing 102 which is disposed adjacent to the fuse tube 24 and thus also the fuse link 23 disposed therein. As shown in the example illustrated embodiment, housing 102 may generally encircle fuse tube 24. It is to be appreciated, however, that such arrangement is provided for exemplary purposes only and that monitoring system 100 may include a housing which does not encircle fuse tube 24 and instead is merely disposed adjacent fuse tube 24.

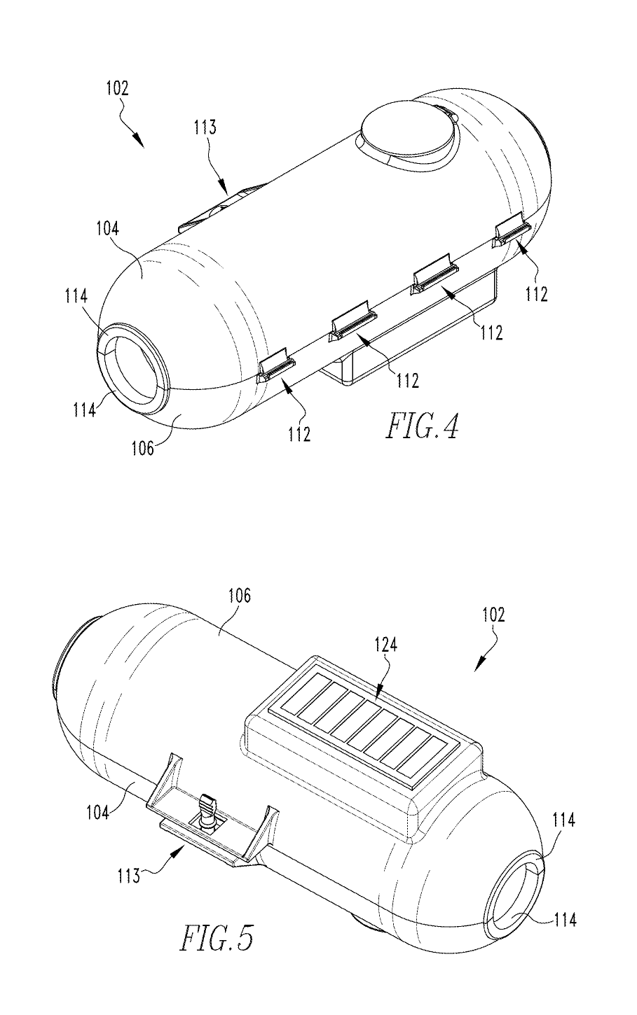

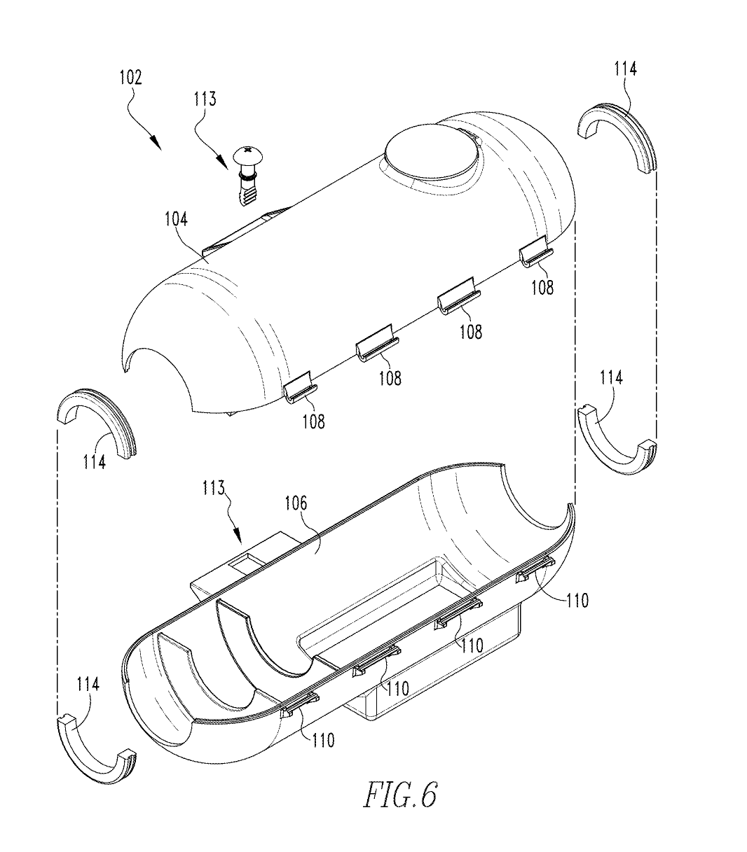

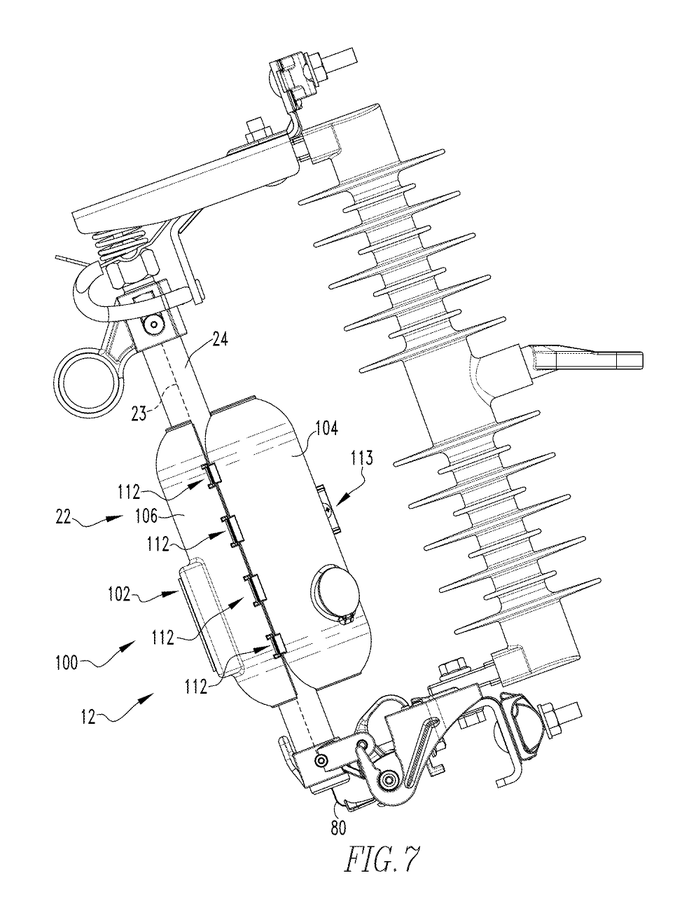

Referring to FIGS. 4-7, housing 102 includes a first portion 104 and a second portion 106 which may be selectively coupled with respect to each other to form a weatherproof enclosure about fuse tube 24. Each of the first portion 104 and the second portion 106 may be formed from a UV stable plastic or other suitable non-conductive material or materials. In the illustrated example embodiment, the first portion 104 and the second portion 106 are moveably coupled with respect to each other via cooperating hinge-like members 108, 110 (FIG. 6) which cooperatively engage to generally form hinge members 112 (FIGS. 4 and 7) such that housing 102 may operate generally in a “clamshell” fashion, and thus be positioned around fuse tube 24 in a manner such as generally shown in FIG. 7. A fastening mechanism 113 (e.g., without limitation, a quarter-turn screw or other suitable mechanism) may be provided on one or both of first and second portions 104, 106 generally opposite hinge members 112 in order to effectively lock housing 102 about fuse tube 24, such as shown in FIGS. 1-3. In order to provide a weatherproof seal with respect to fuse tube 24, housing 102 may include one or more seal members 114 which sealingly engage fuse tube 24. It is to be appreciated that such general arrangement of housing 102 provides for monitoring system 100 to be readily retrofit to existing fuse tubes.

As shown schematically in FIG. 8, system 100 further includes a number of electrical components disposed in or on housing 102 for monitoring one or more aspects of one or both of the fuse tube 24 and/or the fuse link 23 disposed therein. In order to accomplish such monitoring, such electrical components include one or more sources of electrical power 120 (e.g., “Power Source”) electrically coupled to a processing unit 122 (e.g., “Processor”). Such power source(s) 120 may include, for example, without limitation, one or more of: a number of batteries, a number of solar cells 124 (FIG. 5), a system which harvests energy from the power being conducted through the fuse link 23, or any other suitable source of electrical power. Some examples of suitable energy harvesting systems are described in U.S. Application Publication Nos. 2014/0266240 and 2014/0268701 as well as U.S. Pat. Nos. 8,594,956, 8,760,151 and 8,760,254, the contents of which are incorporated by reference herein.

A motion and/or position detecting unit 126 (e.g., “Detector”), such as a 3-axis MEMS accelerometer, gyroscope, or other suitable device, is electrically coupled to the processing unit 122. The motion and/or position detecting unit 126 detects one or both of position and/or movement of the housing 102 (e.g., without limitation, resulting from a blown fuse, fuse maintenance, etc.), and thus the fuse tube 24 to which housing 102 is coupled, and communicates such detections to the processing unit 122.

A current sensing unit 128 (e.g., “Current Sensor”) may be electrically coupled to the processing unit 122 for detecting current passing through the fuse link 23 disposed in the fuse tube 24. Some examples of suitable current sensing units are described in U.S. Application Publication Nos. 2014/0266240 and 2010/0085036 as well as U.S. Pat. No. 8,594,956, the contents of which are incorporated by reference herein.

Continuing to refer to FIG. 8, system 100 further includes a transmitting device 130 (e.g., “Transmitter”) disposed in the housing for transmitting information from the processing device 122 to one or more receiving devices 150 (e.g., “Receiver”) located a distance from the system 100. Such information may be transmitted wirelessly via any suitable means (e.g., without limitation, 900 Mhz radio, cellular, WiFi, Bluetooth, Bluetooth Low Energy, etc.). The receiving device or devices 150 may be collectors, radios, or other suitable devices which are mounted on poles or other suitable locations. Such receiving devices 150 may be part of an existing mesh network (e.g., without limitation, an advanced metering infrastructure network), one or more cellular towers, a handheld device, or any other suitable receiving device.

System 100 may further include one or more additional units, shown generally as 132, which are electrically coupled to processing unit 122 and are structured to sense and/or monitor other conditions of the fuse link, fuse tube assembly, environmental conditions (e.g., without limitation, temperature, humidity), etc. as desired for a particular application.

From the foregoing description, it is to be appreciated that system 100 provides a number of benefits over existing devices. For example, by monitoring the position/movement of the housing 102 (and thus the fuse tube 24 to which it is coupled) via the motion detecting unit 126, system 100 can detect that the fuse link 23 has blown (whether fuse tube 24 has dropped or malfunctioned and stayed in an operating position) and transmit such information to a receiving device 150. Also, fuse links 23 are pulled from time to time for maintenance and replacement. Due to the motion signature differences detected and transmitted by system 100, embodiments of the present concept are able to report and differentiate a blown fuse link 23 from a manually removed fuse link 23.

As another example, today there is little to no data available regarding condition which led up to the blowing of a fuse link. By providing a means for monitoring/recording current passing through the fuse link 23, system 100 can determine if the current has exceeded a predetermined threshold that can be programmed according to the fuse link 23 being used. The system 100 can count such over-current events at its sample rate and can be configured to report when the fuse link 23 experiences over-current for a configured number of counts or time. This allows for a user to investigate the issue before an outage occurs. At the same time, the system 100 can monitor for transient pulses above a certain configurable threshold and it can also be set to report on a certain number of transient counts. This provides diagnostics that are not available today for proactive monitoring of fuse elements that can ultimately be used to determine fuse aging and notify of issues ahead of time.

As yet a further example, a given fuse link rating might be sufficient for a specific application 75% of the time, but during the hottest cooling days of summer with AC on and the link subjected to heating in a cutout at the top of a utility pole, the link may be under rated. By using a temperature sensor as an additional unit 132 in system 100, the system would allow engineers to validate such theories about fuse operations and more accurately size fuse links for specific applications.

From the foregoing it is to be appreciated that embodiments of the present concept not only allow users to quickly identify blown fuses but also to identify possible issues before an outage occurs and more quickly dispatch crews to fix such issues, thus resulting in lower costs to troubleshoot problems and reduced times to correct problems when they do occur.

While example embodiments of the disclosed concept have been shown with respect to a fuse assembly of a drop out fuse cutout, it is also contemplated that the disclosed concept may be employed in other applications where monitoring of the moveable member would be desirable. An example of such other application would be a standard cutout which utilizes a similar arrangement as the fused cutout 12 described herein except there is no fuse element and the fuse tube 24 is simply replaced with a solid copper bar. Indications provided by the monitoring system could include cutout open, closed, current measurement and other non-fuse related measurements.

As another example alternate application would be in an air switch which is similar to a standard cutout except the air switch is a single-piece product rather than the two-piece switch like the cutout. Functions would be the same as the standard cutout with the additional ability to include positive latch indication.

Another example alternate application would be in use with an under oil switch which is designed to go inside oil-filled enclosures. Functions of such an arrangement are the same as cutouts and air switches. In such an application there is a greater importance is on communications to provide status of the switch due to the location and lack of access to the switch. Additional functions of low oil trip, low oil condition, high pressure and oil quality can be measured and communicated.

In yet further example alternate applications would be in rotary switches which are similar to under oil switches except contact closure is performed by rotating a shaft or in magnex switches which are generally special rotary switches which include safety features of overcurrent protection and low-oil trip. Many of the functions of the system 100 described herein could be implemented with the inclusion of radio communication of low oil trip, low oil condition, high pressure and oil quality. While specific embodiments of the disclosed concept have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of the disclosed concept which is to be given the full breadth of the claims appended and any and all equivalents thereof.

What is claimed is:

1. A system for monitoring one or more aspects of a fuse tube assembly of a fuse cutout, the system comprising:
a housing structured to be disposed adjacent to, and coupled to the fuse tube assembly;
a power source disposed in the housing;
a processing unit disposed in the housing and electrically coupled to the power source; and
a motion detecting unit disposed in the housing and electrically coupled to the processing unit, the motion detecting unit being structured to detect one or both of position or movement of the housing.

2. The system of claim 1, further comprising a transmitting unit electrically coupled to the processing unit, the transmitting unit being adapted to transmit information from the processing unit to one or more receiving units positioned a distance from the housing.

3. The system of claim 1, further comprising a current sensing unit disposed in the housing and electrically coupled to the processing unit, the current sensing unit being structured to detect current passing through a fuse link disposed in a fuse tube of the fuse tube assembly.

4. The system of claim 1, wherein the motion detecting unit comprises at least one of an accelerometer or a gyroscope.

5. The system of claim 1, wherein the housing is structured to be disposed around a fuse tube of the fuse tube assembly.

6. The system of claim 5, wherein the housing comprises a first portion and a second portion which are moveably coupled with respect to each other via a number of hinge members.

7. The system of claim 1, wherein the power source comprises a solar cell.

8. The system of claim 1, wherein the power source comprises an energy harvesting system structured to harvest energy from a flow of current passing through a fuse link disposed in a fuse tube of the fuse tube assembly.

9. The system of claim 3, wherein the processing unit is structured to receive and record data along with relevant time information from one or more of the motion detecting unit and current sensing unit.

10. A fuse tube assembly for use in a fuse cutout, the fuse tube assembly comprising:
a fuse tube structured to receive a fuse link therein;
an upper ferrule assembly coupled to the fuse tube at or about an upper end thereof, the upper ferrule assembly structured to engage an upper contact assembly of the fuse cutout;
a lower ferrule assembly coupled to the fuse tube at or about an opposite lower end thereof, the upper ferrule assembly structured to engage a lower contact assembly of the fuse cutout; and
a system for monitoring one or more aspects of the fuse tube assembly, the system comprising:
a housing disposed adjacent to, and coupled to the fuse tube;
a power source disposed in the housing;
a processing unit disposed in the housing and electrically coupled to the power source; and
a motion detecting unit disposed in the housing and electrically coupled to the processing unit, the motion detecting unit being adapted to detect one or both of position or movement of the housing.

11. The fuse tube assembly of claim 10, further comprising a transmitting unit electrically coupled to the processing unit, the transmitting unit being adapted to transmit information from the processing unit to one or more receiving units positioned a distance from the housing.

12. The fuse tube assembly of claim 10, further comprising a current sensing unit disposed in the housing and electrically coupled to the processing unit.

13. The fuse tube assembly of claim 10, wherein the motion detecting unit comprises at least one of an accelerometer or a gyroscope.

14. The fuse tube assembly of claim 10, wherein the housing is disposed around the fuse tube assembly.

15. The fuse tube assembly of claim 14, wherein the housing comprises a first portion and a second portion which are moveably coupled with respect to each other via a number of hinge members.

16. The fuse tube assembly of claim 10, wherein the power source comprises a solar cell.

17. The fuse tube assembly of claim 10, wherein the power source comprises an energy harvesting system structured to harvest energy from a flow of current passing through a fuse link disposed in the fuse tube.

18. A fuse cutout comprising:
an insulator;
a mounting member extending from the insulator for securing the cutout to a utility pole or other structural member;
an upper contact assembly coupled to an upper end of the insulator;
a lower contact assembly coupled to a lower end of the insulator; and
a fuse tube assembly comprising:
a fuse tube structured to receive a fuse link therein;
an upper ferrule assembly coupled to the fuse tube at or about an upper end thereof, the upper ferrule assembly engaged with the upper contact assembly;
a lower ferrule assembly coupled to the fuse tube at or about an opposite lower end thereof, the upper ferrule assembly engaged with the lower contact assembly of the fuse cutout; and
a system for monitoring one or more aspects of the fuse tube assembly, the system comprising:
a housing disposed adjacent to, and coupled to the fuse tube;
a power source disposed in the housing;
a processing unit disposed in the housing and electrically coupled to the power source; and
a motion detecting unit disposed in the housing and electrically coupled to the processing unit, the motion detecting unit being adapted to detect one or both of position or movement of the housing.

19. The fuse cutout of claim 18, wherein the system further comprises a transmitting unit electrically coupled to the processing unit, the transmitting unit being adapted to transmit information from the processing unit to one or more receiving units positioned a distance from the housing.
